(19) United States
(12) Patent Application Publication
(10) Pub. No.: US 2026/0136768 A1
(43) Pub. Date: May 14, 2026

(54) DISPLAY PANEL, METHOD FOR MANUFACTURING SAME, AND DISPLAY DEVICE

(71) Applicant: BOE Technology Group Co., Ltd., Beijing (CN)

(72) Inventor: Yue ZHANG, Beijing (CN)

(73) Assignee: BOE Technology Group Co., Ltd., Beijing (CN)

(21) Appl. No.: 18/683,257

(22) PCT Filed: Mar. 14, 2023
(86) PCT No.: PCT/CN2023/081375

§ 371 Date: Feb. 13, 2024

(51) Int. Cl. H10K 59/122; H10K 59/12; H10K 59/35; H10K 102/00

(52) U.S. Cl. CPC H10K 59/122; H10K 59/1201; H10K 59/353; H10K 2102/351

(57) ABSTRACT

Provided is a display panel including: a substrate, a plurality of pixels, and a pixel definition layer. In a plurality of sub-pixels contained in each pixel, at least two sub-pixels are disposed in different rows, homochromatic sub-pixels are disposed in a same column, and heterochromatic sub-pixels are disposed in different columns. The pixel definition layer includes a plurality of definition portions and a plurality of communication portions. The plurality of sub-pixels are within a plurality of openings defined by the definition portions and the communication portions. Each definition portion is configured to define, in the pixel row direction and the pixel column direction, the respective heterochromatic sub-pixels adjacent to each other. Each communication portion is configured to be in communication, in the pixel column direction, with the respective homochromatic sub-pixels adjacent to each other. A thickness of the definition portion is greater than a thickness of the communication portion.

### CROSS-REFERENCE TO RELATED APPLICATION

The present disclosure is a U.S. national stage of international application No. PCT/CN2023/081375, filed on Mar. 14, 2023, the content of which is herein incorporated by reference in its entirety.

### TECHNICAL FIELD

The present disclosure relates to the field of display technologies, and in particular, relates to a display panel, a method for manufacturing the same, and a display device.

### BACKGROUND

Organic light-emitting diode (OLED) display panels are widely used in various types of display devices due to their advantages of self-emission, fast response, wide viewing angle, high brightness, and vivid colors.

### SUMMARY

Embodiments of the present disclosure provide a display panel, a method for manufacturing the same, and a display device. The technical solutions are as follows.

According to some embodiments of the present disclosure, a display panel is provided. The display panel includes:
a substrate;
a plurality of pixels disposed on a side of the substrate and arranged in an array, each of the pixels including a plurality of sub-pixels of different colors; wherein in each of the pixels, at least two sub-pixels are disposed in different rows, homochromatic sub-pixels are disposed in a same column, heterochromatic sub-pixels are disposed in different columns, and an area of an orthographic projection of each of the sub-pixels on the substrate is positively correlated with a decay rate of luminance of the sub-pixel; and
a pixel definition layer, disposed on a side of the substrate and including a plurality of definition portions and a plurality of communication portions alternately arranged along a pixel column direction; wherein a plurality of openings are defined by the plurality of definition portions and the plurality of communication portions in a pixel row direction and the pixel column direction, and the plurality of sub-pixels in the display panel are disposed within the plurality of openings, the pixel row direction being intersected with the pixel column direction; and each of the definition portions is configured to define, in the pixel row direction and the pixel column direction, the respective heterochromatic sub-pixels adjacent to each other, each of the communication portions is configured to be in communication, in the pixel column direction, with the respective homochromatic sub-pixels adjacent to each other, and a thickness of the definition portion is greater than a thickness of the communication portion.

In some embodiments, in each column of the pixels, each column of the sub-pixels disposed at two edges and the communication portion in communication with each column of the sub-pixels are successively arranged along the pixel column direction, and the communication portion in communication with each column of the sub-pixels covers a portion, extending away from the definition portion in the pixel column direction, of each of the sub-pixels; and in each column of the sub-pixels disposed in a middle, the respective sub-pixels and the communication portion in communication with the respective sub-pixels are successively arranged along the pixel row direction.

In some embodiments, portions, covering the respective sub-pixels, of the communication portion are in communication with each other in the pixel row direction.

In some embodiments, portions, covering the respective sub-pixels, of the communication portion are independent from each other in the pixel row direction.

In some embodiments, in the pixel row direction, an orthographic projection on the substrate of the portion, covering each of the sub-pixels, of the communication portion is overlapped with a spacing region between adjacent two of the sub-pixels.

In some embodiments, in each column of the pixels, the respective sub-pixels and the communication portion in communication with the respective sub-pixels are alternately arranged in the pixel row direction.

In some embodiments, an orthographic projection of the communication portion in communication with any adjacent two of the sub-pixels on the substrate covers a spacing region between the adjacent two sub-pixels.

In some embodiments, an orthographic projection of the sub-pixel on the substrate is any one of the following shapes: rectangular, polygonal, L-shaped, T-shaped, or cross-shaped.

In some embodiments, in the plurality of sub-pixels in each of the pixels, in the pixel column direction, each of the sub-pixels disposed at the two edges is L-shaped or T-shaped, and the sub-pixel disposed in the middle is T-shaped or cross-shaped.

In some embodiments, in the pixel row direction, in the pixels in first and last rows, each of the sub-pixels disposed at the two edges is L-shaped, and the sub-pixel disposed in the middle is T-shaped or cross-shaped; and
in the pixels in rows other than the first and last rows, each of the sub-pixels disposed at the two edges is T-shaped, and the sub-pixel disposed in the middle is cross-shaped.

In some embodiments, an orthographic projection of each of the pixels on the substrate is triangular, and each of the pixels includes a first sub-pixel, a second sub-pixel, and a third sub-pixel of different colors; wherein
the first sub-pixel and the second sub-pixel are disposed in a same row, and are both disposed in a row different from the third sub-pixel; and the third sub-pixel includes a first portion, a second portion, and a third portion arranged in the pixel column direction, wherein the first portion and the first sub-pixel are disposed in a same column, the third portion and the second sub-pixel are disposed in a same column, and the second portion, the first sub-pixel, and the second sub-pixel are disposed in different columns.

In some embodiments, the first sub-pixel is a red sub-pixel, the second sub-pixel is a green sub-pixel, and the third sub-pixel is a blue sub-pixel; and
an area of an orthographic projection of the first sub-pixel on the substrate is equal to an area of an orthographic projection of the second sub-pixel on the substrate, and both of the areas are smaller than an area of an orthographic projection of the third sub-pixel on the substrate.

In some embodiments, the pixel definition layer includes a first pixel definition layer and a second pixel definition layer that are disposed on a side of the substrate; wherein
the first pixel definition layer includes the plurality of definition portions and the second pixel definition layer includes the plurality of communication portions; and
the first pixel definition layer is made of a lyophobic material, and the second pixel definition layer is made of a lyophilic material.

In some embodiments, in a direction perpendicular to the substrate, a cross-section of the first pixel definition layer is in a regularly trapezoidal shape.

In some embodiments, a thickness of the definition portion ranges from 1.2 micrometers to 1.5 micrometers, and a thickness of the communication portion ranges from 0.3 micrometers to 1 micrometer.

In some embodiments, the sub-pixel includes an anode layer, a light-emitting layer, and a cathode layer that are successively stacked in a direction away from the substrate;
wherein the anode layer is disposed within the opening, the definition portion is configured to define the light-emitting layers contained in the respective heterochromatic sub-pixels adjacent to each other, and the communication portion is configured to be in communication with the light-emitting layers contained in the respective homochromatic sub-pixels adjacent to each other.

According to some embodiments of the present disclosure, a method for manufacturing a display panel is provided. The method is applicable to manufacturing the display panel as described above. The method includes:
providing a substrate;
forming an anode layer on a side of the substrate;
forming a pixel definition layer on a side, distal from the substrate, of the anode layer; wherein the formed pixel definition layer includes a plurality of definition portions and a plurality of communication portions alternately arranged along a pixel column direction, a thickness of the definition portion is greater than a thickness of the communication portion, and a plurality of openings are defined by the plurality of definition portions and the plurality of communication portions in a pixel row direction and the pixel column direction, the pixel row direction being intersected with the pixel column direction;
forming light-emitting layers in the plurality of openings; wherein each of the definition portions is configured to define, in the pixel row direction and the pixel column direction, the light-emitting layers in respective heterochromatic sub-pixels adjacent to each other, and each of the communication portions is configured to be in communication, in the pixel column direction, with the light-emitting layers in respective homochromatic sub-pixel adjacent to each other; and
acquiring a plurality of sub-pixels by forming a cathode layer on a side, distal from the substrate, of the light-emitting layer;
wherein each of the formed pixels includes a plurality of sub-pixels of different colors, in each of the pixels, at least two sub-pixels are disposed in different rows, the respective sub-pixels are disposed in different columns, and an area of an orthographic projection of each of the sub-pixels on the substrate is positively correlated with a decay rate of the sub-pixel.

In some embodiments, forming the pixel definition layer on the side, distal from the substrate, of the anode layer includes:
forming a first pixel definition layer and a second pixel definition layer on the side, distal from the substrate, of the anode layer using a half-tone mask plate; wherein
the formed first pixel definition layer includes the plurality of definition portions and the formed second pixel definition layer includes the plurality of communication portions; and the first pixel definition layer is made of a lyophobic material, and the second pixel definition layer is made of a lyophilic material.

In some embodiments, forming the light-emitting layers in the plurality of openings includes:
forming the light-emitting layers by printing light-emitting materials in the plurality of openings by an inkjet printing process.

According to some embodiments of the present disclosure, a display device is provided. The display device includes a power supply assembly and the display panel as described above.
wherein the power supply assembly is coupled to the display panel and is configured to supply power to the display panel.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a schematic diagram of a pixel definition layer and a pixel layout in some practices;

FIG. 2 is a schematic structural diagram of a pixel undesirable phenomenon illustrated on the basis of the structure illustrated in FIG. 1;

FIG. 3 is a schematic structural diagram of a display panel according to some embodiments of the present disclosure;

FIG. 4 is a cross-sectional schematic diagram of the structure illustrated in FIG. 3 according to some embodiments of the present disclosure;

FIG. 5 is a schematic structural diagram of another display panel according to some embodiments of the present disclosure;

FIG. 6 is a cross-sectional schematic diagram of the structure illustrated in FIG. 5 according to some embodiments of the present disclosure;

FIG. 7 is a schematic diagram of a pixel layout in a display panel according to some embodiments of the present disclosure;

FIG. 8 is a schematic structural diagram of yet another display panel according to some embodiments of the present disclosure;

FIG. 9 is a schematic structural diagram of yet still another display panel according to some embodiments of the present disclosure;

FIG. 10 is a cross-sectional schematic diagram of the structure illustrated in FIG. 9 according to some embodiments of the present disclosure;

FIG. 11 is a schematic structural diagram of yet still another display panel according to some embodiments of the present disclosure;

FIG. 12 is a cross-sectional schematic diagram of the structure illustrated in FIG. 11 according to some embodiments of the present disclosure;

FIG. 13 is a schematic structural diagram of yet still another display panel according to some embodiments of the present disclosure;

FIG. 14 is a cross-sectional schematic diagram of the structure illustrated in FIG. 13 according to some embodiments of the present disclosure;

FIG. 15 is a flowchart of a method for manufacturing a display panel according to some embodiments of the present disclosure; and

FIG. 16 is a schematic structural diagram of a display device according to some embodiments of the present disclosure.

### DETAILED DESCRIPTION

The present disclosure is described in further detail with reference to the accompanying drawings, to clearly present the objects, technical solutions, and advantages of the present disclosure.

In some practices, the OLED display panel generally includes a substrate, a pixel definition layer disposed on a side of the substrate and having a plurality of openings, and a plurality of pixels disposed within the plurality of openings and defined by the pixel definition layer. The pixel includes an anode layer, a light-emitting layer, and a cathode layer that are successively stacked in a direction away from the substrate. At present, the light-emitting layer is typically formed by printing light-emitting materials within the openings in the pixel definition layer by an inkjet printing process.

However, due to the limitation of process precision, film layers formed at different positions using the inkjet printing process have a poor thickness uniformity, which affects the display effect of the display panel.

At present, as documented in some practices, the inkjet printing process is often used to print light-emitting materials (which is also referred to as ink) in the openings included in the pixel definition layer to form the light-emitting layer, which belongs to a kind of OLED film-forming method. This method has the advantage of high material utilization and is considered to be an important way to achieve mass production of large-sized OLED display panels. However, in one aspect, in the process of inkjet printing, the ink climbs along the pixel definition layer at the edges of the openings, and thus the film formation is uneven at different locations. In another aspect, during the drying process after the inkjet printing, the ink evaporates faster in the edge region, which causes the ink to flow from the center to the edge, i.e., to migrate to the edge, and the ink ultimately deposits at the edge, resulting in the formation of a deposition morphology with the thick edge and thin center (known as the “coffee ring effect”), which is also manifested as an uneven film formation. Therefore. the OLED light-emitting elements have poor light-emitting uniformity, which results in a poor display effect of the display panel.

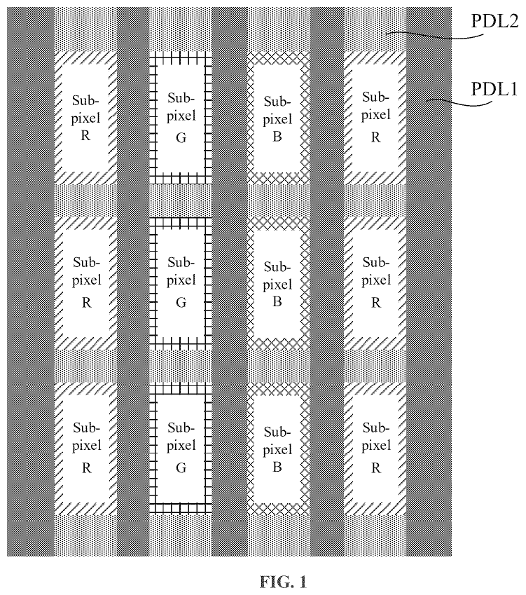

To this end, a line bank type (i.e., linear communication type) pixel structure as illustrated in FIG. 1 is also provided in some practices to solve the problem of poor film formation uniformity. Referring to FIG. 1, the line bank type pixel structure refers to a structure in which homochromatic sub-pixels (e.g., red sub-pixels R) are intercommunicated in the same column by a pixel definition layer (PDL) PDL1 made of a lyophilic material, and the heterochromatic sub-pixels (e.g., a red sub-pixel R, a green sub-pixel G, and a blue sub-pixel B) are defined and separated from each other in the same row by a pixel definition layer (PLD2) made of a lyophobic material.

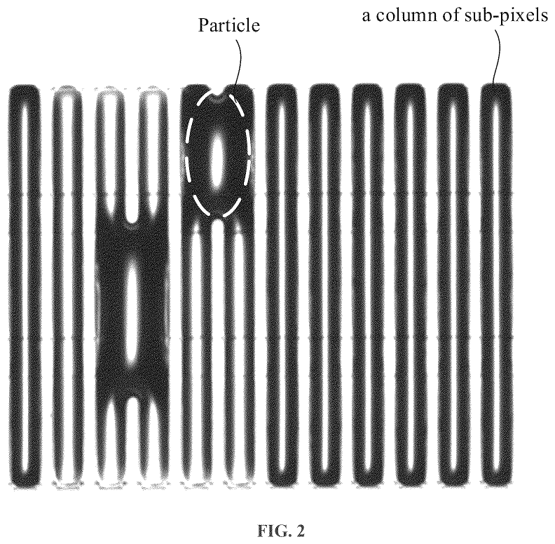

For the line bank type pixel structure, the printed ink climbs only at the most marginal position of a column of pixels, and the homochromatic sub-pixels in the middle have a uniform film formation effect, such that the luminescence uniformity is improved. However, it was found in the test that the communication of the line bank type pixel structure makes the OLED susceptible to particles. Specifically, referring to FIG. 2, when the ink in the light-emitting region is unable to wrap around the particles during ink printing, the particles exert a tensile force on the ink, such that a large amount of ink is adsorbed in the vicinity of the particles, and thus the ink decreases in the distant region away from the particles, causing a pixel undesirable phenomenon in the same column. In addition, in the actual inkjet printing process, due to the unavoidable tilting of the printer, the printed ink inevitably aggregates on one side by gravity, which affects the effect of the film formation, leading to the poor display effect.

Based on this, some embodiments of the present disclosure provide a new pixel structure, which solves the problem of poor film formation uniformity described above, and avoids the pixel undesirable phenomenon caused by particles.

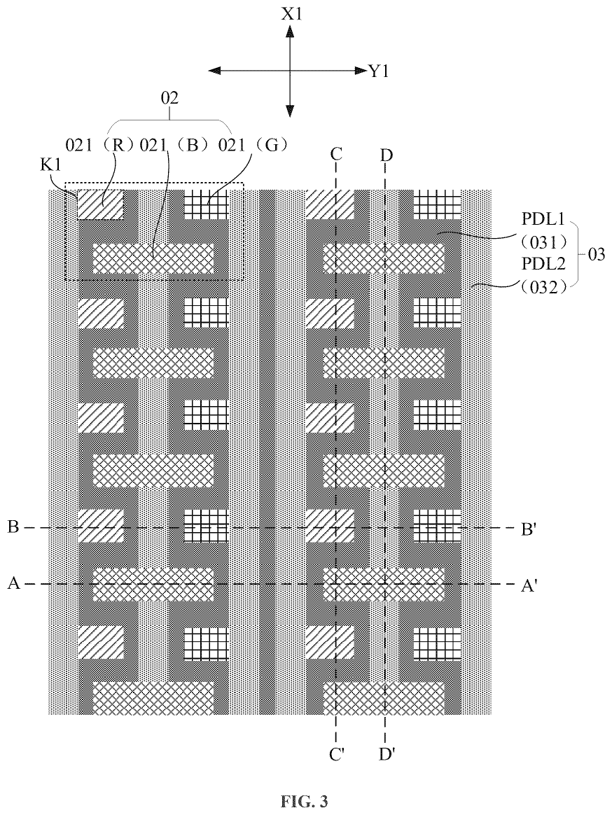

FIG. 3 is a schematic structural diagram of a display panel according to some embodiments of the present disclosure. As shown in FIG. 3, the display panel includes:
a substrate 01;
a plurality of pixels 02, disposed on a side of the substrate 01 and arranged in an array; and
a pixel definition layer PDL 03 disposed on a side of the substrate 01.

Each of the pixels 02 includes a plurality of sub-pixels 021 of different colors. In each of the pixels 02, at least two sub-pixels 021 are disposed in different rows, homochromatic (i.e., same-color) sub-pixels 021 are disposed in the same column, and heterochromatic (i.e., different-color) sub-pixels 022 are disposed in different columns. That is, the plurality of sub-pixels 021 in each of the pixels 02 are arranged in a non-linear manner distinguished from FIG. 1. In some embodiments, each pixel 02 illustrated in FIG. 3 includes three sub-pixels 021 of different colors. In these three sub-pixels 021 illustrated in FIG. 3, two of those three sub-pixels 021 are disposed in the same row and the remaining one sub-pixel 021 is disposed in a different row.

The pixel definition layer 03 has a plurality of definition portions 031 and a plurality of communication portions 032 alternately arranged along a pixel column direction Y1. A plurality of openings K1 are defined by the plurality of definition portions 031 and the plurality of communication portions 032 in a pixel row direction X1 and the pixel column direction Y1. The plurality of the sub-pixels 021 contained in the display panel are disposed within the plurality of openings K1. The pixel row direction X1 is intersected with the pixel column direction Y1. In some embodiments, referring to FIG. 1, in the display panel illustrated in FIG. 1, the pixel column direction Y1 is perpendicular to the pixel row direction X1.

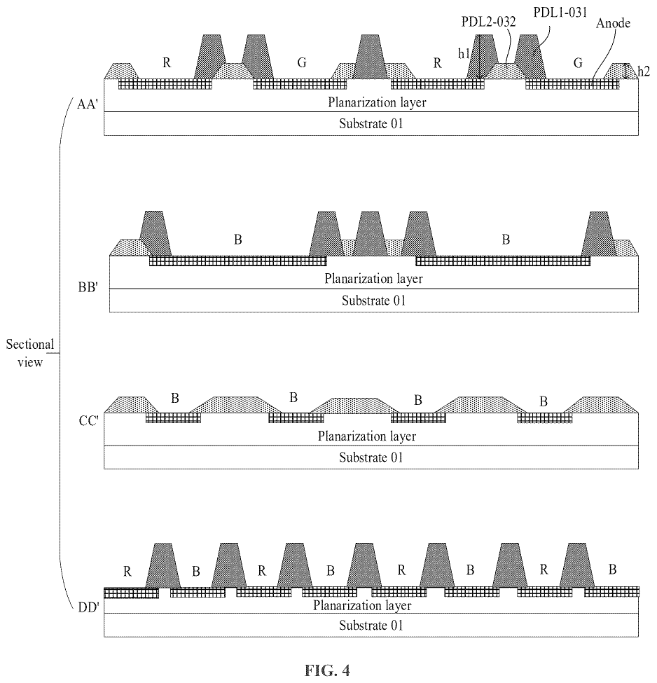

Moreover, each of the definition portions 031 is configured to define, in the pixel row direction X1 and the pixel column direction Y1, respective heterochromatic sub-pixels 021 adjacent to each other, and each of the communication portions 032 is configured to be in communication, in the pixel column direction Y1, with respective homochromatic sub-pixels 021 adjacent to each other. In addition, referring to a cross-sectional view of FIG. 3 illustrated in FIG. 4 in different directions (including four directions, namely, AA′, BB′, CC′, and DD′), a thickness h1 of the definition portion 031 is greater than a thickness h2 of the communication portion 032. A thickness direction refers to a direction perpendicular to the substrate 01.

It should be noted that the definition portion 031 configured to define the adjacent respective heterochromatic sub-pixels 021 means that, for each of the sub-pixels 021, the ink of the inkjet printing is blocked by the definition portion 031, and thus the respective heterochromatic sub-pixels are isolated from each other. Accordingly, the definition portion 031 is made of a lyophobic material. The communication portion 032 configured to be in communication with the adjacent respective homochromatic sub-pixels 021 means that, for the adjacent homochromatic sub-pixels 021, the ink of the inkjet printing flows through a side, distal from the substrate 01, of the communication portion 032, such that the respective homochromatic sub-pixels are intercommunicated. Accordingly, the communication portion 032 is made of a lyophilic material.

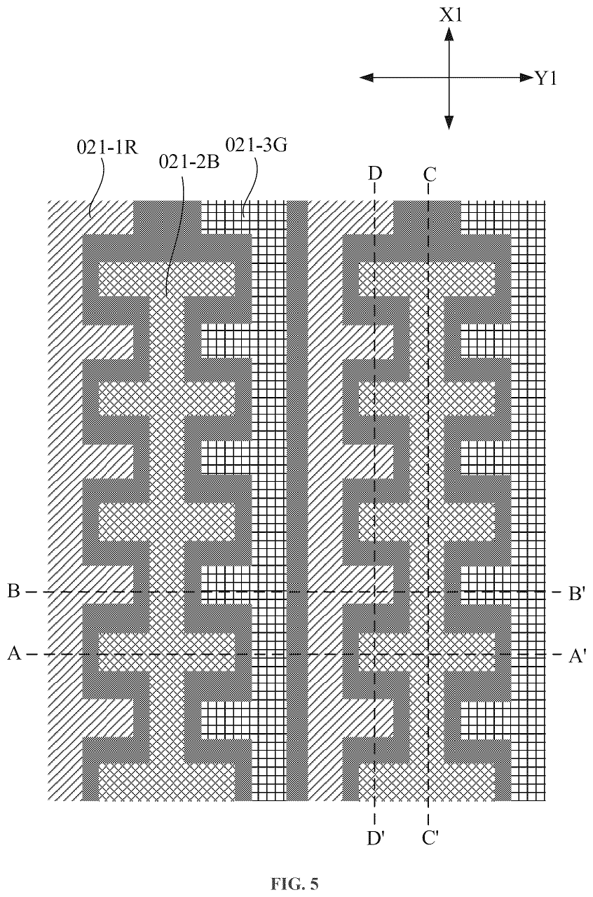

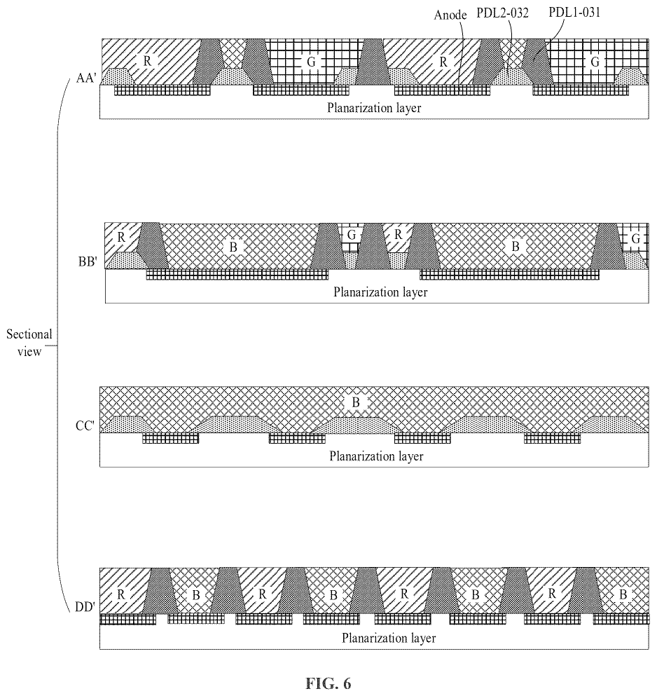

In some embodiments, based on FIG. 3, FIG. 5 illustrates a schematic structural diagram in which homochromatic sub-pixels 031 in the same column are communicated by the communication portion 032. FIG. 6 illustrates a cross-sectional diagram of the structure illustrated in FIG. 5 in four directions, AA′, BB′, CC′ and DD′.

On the basis of the above design, in one aspect, along the pixel column direction Y1, the ink ejected from different nozzles in the printer is intercommunicated, such that the problem of poor film formation uniformity caused by the errors in the amount of ink ejected between the plurality of nozzles is addressed. In another aspect, it is also possible to make the printed ink climb only at the position of the most edge of the pixels in the same column, such that the sub-pixels of the same color in the middle achieve a uniform film formation effect, and thus the luminescence uniformity is improved. In another aspect, the pulling force of the particles on the ink is reduced, and thus the undesirable phenomena caused by the particles within the pixels are alleviated. Therefore, the film formation uniformity when forming the OLED device by printing is improved, and the luminescence uniformity is ensured to be good, such that the display effect of the display panel is good.

Furthermore, in some embodiments of the present disclosure, an area of an orthographic projection of each of the sub-pixels 021 on the substrate 01 is positively correlated with a decay rate of luminance of the sub-pixel 021. That is, in the plurality of sub-pixels 021 included in each of the pixels 02, the sub-pixel 021 with the fastest decay rate of the luminance has the largest area; conversely, the sub-pixel 021 with the slowest decay rate of the luminance has a smaller area.

In some embodiments, referring to FIG. 1, on the basis that each of the pixels 02 includes a red sub-pixel R, a green sub-pixel G, and a blue sub-pixel B, an area of the blue sub-pixel B is defined to be the largest because the blue sub-pixel B has the fastest decay rate. In this way, the problem of color cast caused by different sub-pixels 021 in a pixel 02 having different decay rates is also addressed, such that the display effect of the display panel is further ensured to be good.

In summary, some embodiments of the present disclosure provide a display panel. The display panel includes the substrate, the plurality of pixels disposed on a side of the substrate and arranged in an array, and the pixel definition layer disposed on a side of the substrate. In the plurality of sub-pixels of different colors included in each of the pixels, at least two sub-pixels are disposed in different rows, the heterochromatic sub-pixels are disposed in different columns, and the homochromatic sub-pixels are disposed in the same column. The pixel definition layer has the communication portion and the definition portion, and the plurality of sub-pixels are disposed within the plurality of openings defined by the communication portion and the definition portion. The communication portion is capable of being in communication with the respective homochromatic sub-pixels in the column direction, the definition portion is capable of defining the respective heterochromatic sub-pixels in the pixel row direction and the pixel column direction, and the thickness of the communication portion is smaller than the thickness of the definition portion. In this way, in one aspect, the sub-pixels of different colors are reliably defined, and in another aspect, the ink of the inkjet printing flows in the same column only towards two sides of that column, such that the film formation uniformity in the middle position is good, and thus the display effect of the display panel is good.

In some embodiments, referring to FIG. 4 and FIG. 6, the sub-pixel 021 according to some embodiments of the present disclosure includes an anode layer Anode, a light-emitting layer EL, and a cathode layer Cathode (not shown in the figures) that are successively stacked along a direction away from the substrate 01. The printed ink in the opening K1 of the pixel definition layer 03 is the light-emitting layer EL, identified in FIG. 4 and FIG. 6 by colors R, G, and B. That is, the anode layer Anode is disposed within the opening K1. The definition portion 031 is configured to define the light-emitting layers EL contained in the respective heterochromatic sub-pixels 021 adjacent to each other, and the communication portion 032 is configured to be in communication with the light-emitting layers EL contained in the respective homochromatic sub-pixels 021 adjacent to each other.

In some embodiments, the anode layer Anode is made of indium tin oxide (ITO). Because ITO is a transparent material, the light transmittance of the display panel is ensured to be good. The anode layer Anode is made of other transparent materials. In addition, a package layer is provided on a side, distal from the substrate 01, of the cathode layer Cathode, such that the sub-pixel is reliably packaged. As illustrated in FIG. 4 and FIG. 6, a planarization layer is also provided between the anode layer Anode and the substrate 01, which facilitates the reliable film formation on a side, away from the substrate 01, of the planarization layer. In some embodiments, the planarization layer is made of a resin material.

In some embodiments, referring to FIG. 3 to FIG. 6, the pixel definition layer 03 according to some embodiments of the present disclosure includes a first pixel definition layer PDL1 and a second pixel definition layer PDL2 that are disposed on a side of the substrate 01.

The first pixel definition layer PDL1 includes a plurality of definition portions 031 and the second pixel definition layer PDL2 includes a plurality of communication portions 032. Furthermore, as described above, the first pixel definition layer PDL1 is made of a lyophobic material and the second pixel definition layer PDL2 is made of a lyophilic material.

In some embodiments, referring to FIG. 4 and FIG. 6, a cross-section of the first pixel definition layer PDL1 is in a regularly trapezoidal shape in the direction perpendicular to the substrate 01. In some other embodiments, the cross-section of the first pixel definition layer PDL1 is in other shapes, such as an inverted trapezoid. Similarly, the shape of a cross-section of the second pixel definition layer PDL2 is not repeated herein.

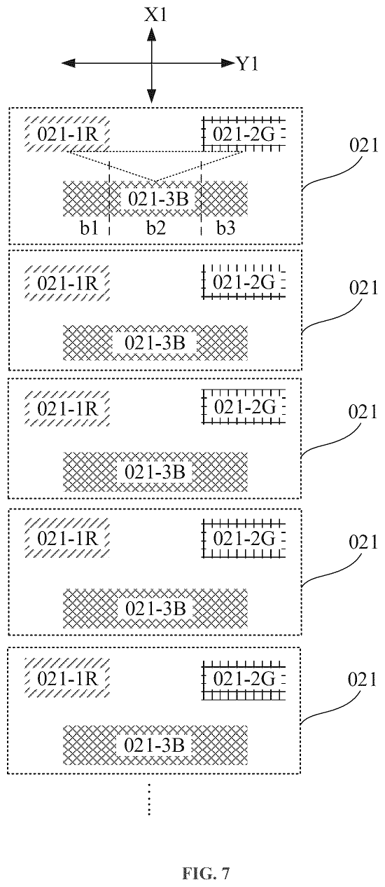

In some embodiments, based on FIG. 3 to FIG. 6, FIG. 7 illustrates a schematic diagram, of a pixel arrangement. As shown in FIG. 7, in some embodiments of the present disclosure, the orthographic projection of each of the pixels 02 on the substrate 01 is triangular, and each of the pixels 02 includes a total of three sub-pixels 021 of different colors (a first sub-pixel 021-1, a second sub-pixel 021-2, and a third sub-pixel 021-3). In some embodiments, as described above, the first sub-pixel 021-1 is a red sub-pixel (identified as 021-1R), the second sub-pixel 021-2 is a green sub-pixel (identified as 021-2G), and the third sub-pixel 021-3 is a blue sub-pixel (identified as 021-3B).

The first sub-pixel 021-1R and the second sub-pixel 021-2G are disposed in the same row, and are both disposed in a row different from the third sub-pixel 021-3B.

The third sub-pixel 021-3B includes a first portion b1, a second portion b2, and a third portion b3 that are arranged along the pixel column direction Y1. The first portion b1 and the first sub-pixel 021-1R are disposed in the same column, the third portion b3 and the second sub-pixel 021-2G are disposed in the same column, and the second portion b2, the first sub-pixel 021-1R, and the second sub-pixel 021-2G are disposed in different columns. That is, along the pixel row direction X1, the first sub-pixel 021-1R, the second portion b2 of the third sub-pixel 021-3B, and the second sub-pixel 021-2G are successively arranged.

In some embodiments, an area of an orthographic projection of the first sub-pixel 021-1R (i.e., the red sub-pixel) on the substrate 01 is equal to an area of an orthographic projection of the second sub-pixel 021-2G (i.e., the green sub-pixel) on the substrate 01, and both of the areas are smaller than an area of an orthographic projection of the third sub-pixel 021-3B (i.e., the blue sub-pixel) on the substrate 01. That is, in some embodiments of the present disclosure, on the basis that the pixel 02 includes the red sub-pixel, the green sub-pixel, and the blue sub-pixel, the area of the blue sub-pixel is defined to be larger than the area of the red sub-pixel and larger than the area of the green sub-pixel, such that a light-emitting area of the blue sub-pixel is larger than a light-emitting area of the red sub-pixel and larger than a light-emitting area of the green sub-pixel, and thus the problem of color cast caused by the fast decay rate of the blue sub-pixel is improved.

Optionally, the orthographic projection of the sub-pixel 021 on the substrate 01 as documented in some embodiments of the present disclosure is any of the following shapes: rectangular, polygonal (i.e., non-rectangular), L-shaped, T-shaped, or cross-shaped.

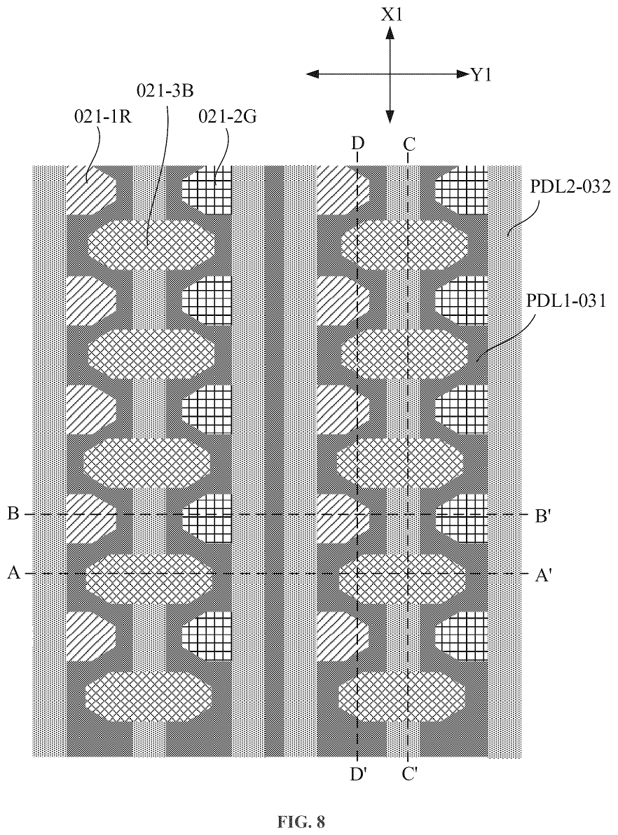

In some embodiments, in FIG. 3, FIG. 5, and FIG. 7 described above, the orthographic projection of the sub-pixel 021 on the substrate 01 is rectangular. As another example, referring to another display panel illustrated in FIG. 8, the display panel includes a sub-pixel 021 whose orthographic projection on the substrate 01 is polygonal (e.g., octagonal). The polygon, as opposed to a rectangle, reduces the pinning effect of inkjet-printed ink at the edges and further allows the printed light-emitting material to form a more uniform film at the edges. In addition, the polygon also increases an aperture ratio of the pixel, such that the luminance is good.

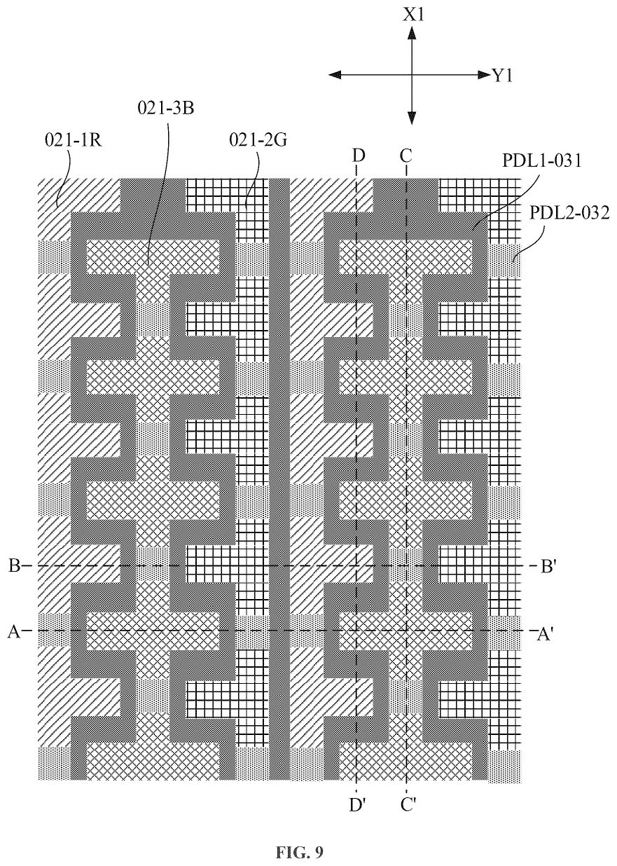

As a further example, referring to a schematic structural diagram of a display panel illustrated in FIG. 9, in the plurality of sub-pixels 021 included in each of the pixels 02, in the pixel column direction Y1, the sub-pixels 021 (e.g., the red sub-pixel 021-1R and the green sub-pixel 021-2G) respectively disposed at two edges are L-shaped or T-shaped, and the sub-pixel 021 (e.g., the blue sub-pixel 021-3B) disposed in the middle is T-shaped or cross-shaped.

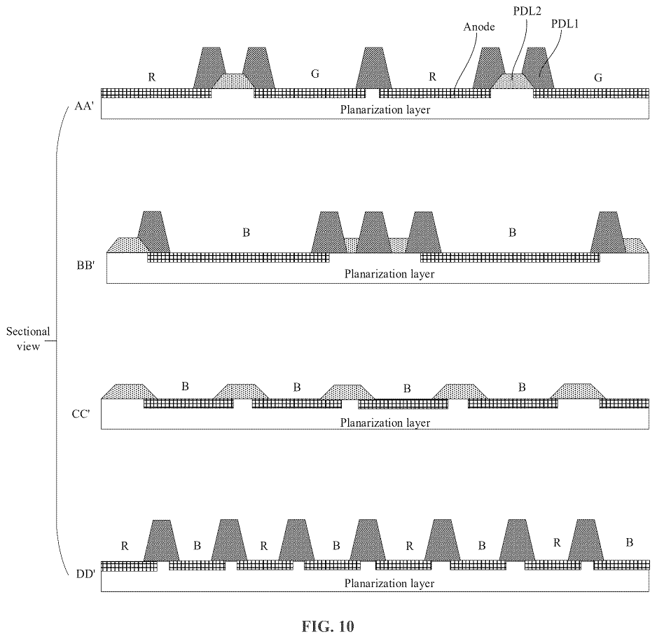

In some embodiments, in the display panel illustrated in FIG. 9, in the pixel row direction X1, in the pixels 02 in the first and last rows, the sub-pixels 021 (including the red sub-pixel 021-1R and the green sub-pixel 021-2G) respectively disposed at the two edges are L-shaped, and the sub-pixel 021 (e.g., the blue sub-pixel 021-3B) disposed in the middle is T-shaped or cross-shaped. In the pixels 02 in other rows other than the first and last rows, the sub-pixels 021 (including the red sub-pixel 021-1R and the green sub-pixel 021-2G) respectively disposed at the two edges are T-shaped, and the sub-pixel 021 (i.e., the blue sub-pixel 021-3B) disposed in the middle is cross-shaped. By designing the L-shape, T-shape, and the cross-shape, the light-emitting area of the pixel is further expanded, and the aperture ratio is increased. Optionally, FIG. 10 also illustrates a cross-sectional view of the display panel shown in FIG. 9 in a total of four directions, AA′, BB′, CC′, and DD′. In some embodiments, the sub-pixels 021 are provided in other shapes, which are not limited herein.

In some embodiments, FIG. 10 also illustrates a cross-sectional view of the display panel shown in FIG. 9 in a total of 4 directions, AA′, BB′, CC′, and DD′.

In some embodiments, referring to FIG. 3 and FIG. 8, in each column of pixels 02 documented in some embodiments of the present disclosure, each column of sub-pixels 021 disposed at two edges and the communication portion 032 in communication with each column of sub-pixels 021 are successively arranged along the pixel column direction Y1, and the communication portion 032 in communication with each column of sub-pixels 021 covers a portion, extending away from the definition portion 031 in the pixel column direction Y1, of each of the sub-pixels 021. That is, the communication portion 032 is disposed on a side of each column of sub-pixels 021 disposed at the edge. Moreover, in each column of sub-pixels 021 disposed in the middle, respective sub-pixels 021 and the communication portions 032 in communication with the respective sub-pixels 021 are alternately arranged in the pixel row direction X1.

Based on the embodiments described above, in some other embodiments, referring to FIG. 3 and FIG. 8, portions, covering the sub-pixels 021, of the communication portion 032 are intercommunicated in the pixel row direction X1. That is, the communication portion 032 is wholly disposed on a side of each column of sub-pixels 021 disposed at the edge to be in communication with the respective homochromatic sub-pixels 021 disposed in the same column.

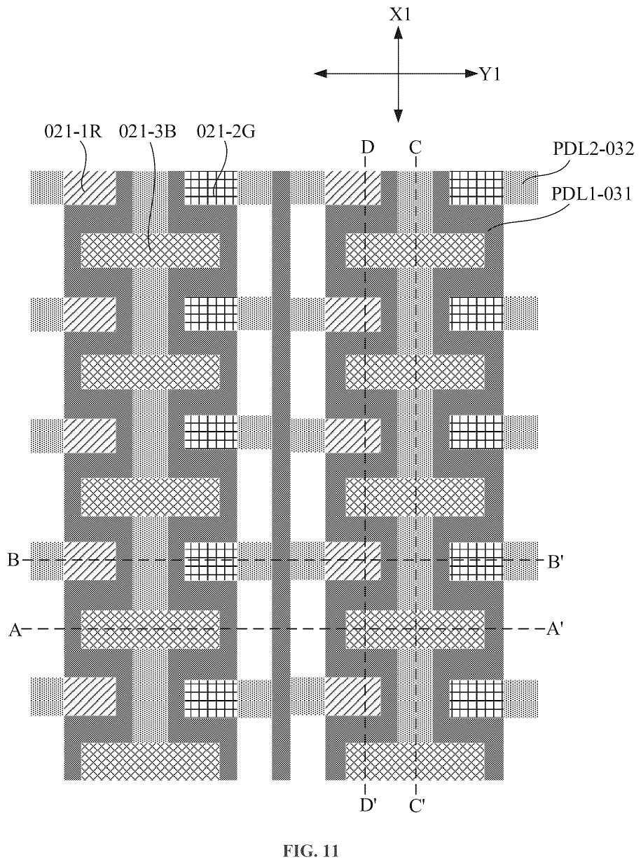

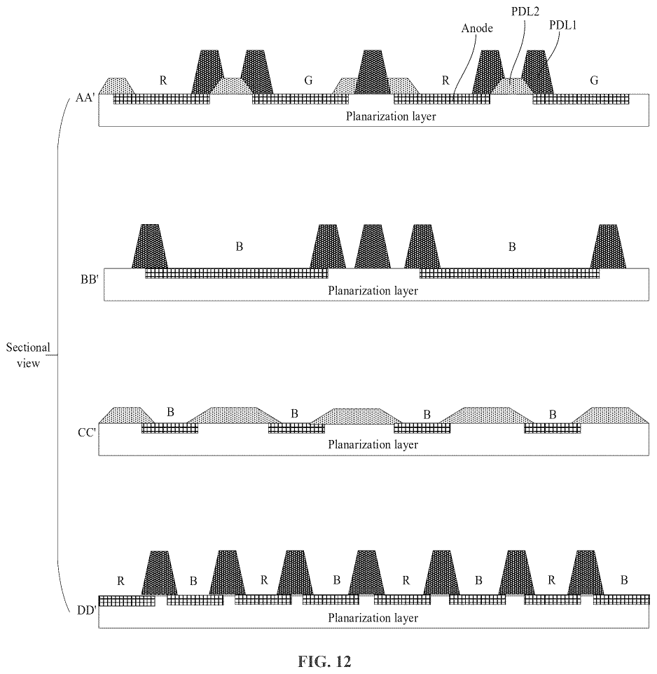

In some embodiments, referring to FIG. 11, the portions, covering the sub-pixels 021, of the communication portion 032 are independent from each other in the pixel row direction X1. That is, some positions of the communication portion 032, which is disposed on an edge as a whole in FIG. 3 and FIG. 8, are dug out, and the dugout positions are spacing regions between every adjacent two sub-pixels 021 in the same column. The white-filled portion of FIG. 11 is the spacing region, and there is no communication portion 032 in the spacing region. In other words, for every column of sub-pixels 021 disposed in two edges of each column of pixels 02, the communication portion 032 is provided only on a side of each of the sub-pixels 021 in the row direction X1, and the communication portion 032 is not provided between the spacing regions of every adjacent two sub-pixels 021. In this way, the holding volume of the ink for the inkjet printing is increased, and thus the risk of ink overflow is reduced. Optionally, FIG. 12 also illustrates a cross-sectional view of the display panel shown in FIG. 11 in a total of 4 directions, AA′, BB′, CC′, and DD′.

In some embodiments, in conjunction with FIG. 11, in the pixel row direction X1, an orthographic projection on the substrate 01 of the portion, covering each of the sub-pixels 021, of the communication portion 032 is overlapped with the spacing region between adjacent two sub-pixels 021. That is, a small amount of communication portion 032 is arranged within the white-filled spacing region, but the portions, covering the sub-pixels 021, of the communication portions 032 still remain independent from each other in the pixel row direction X1.

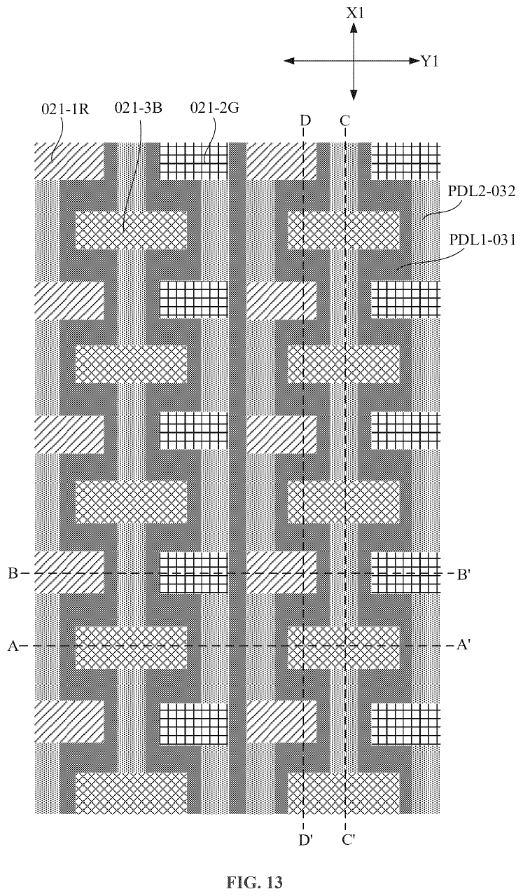

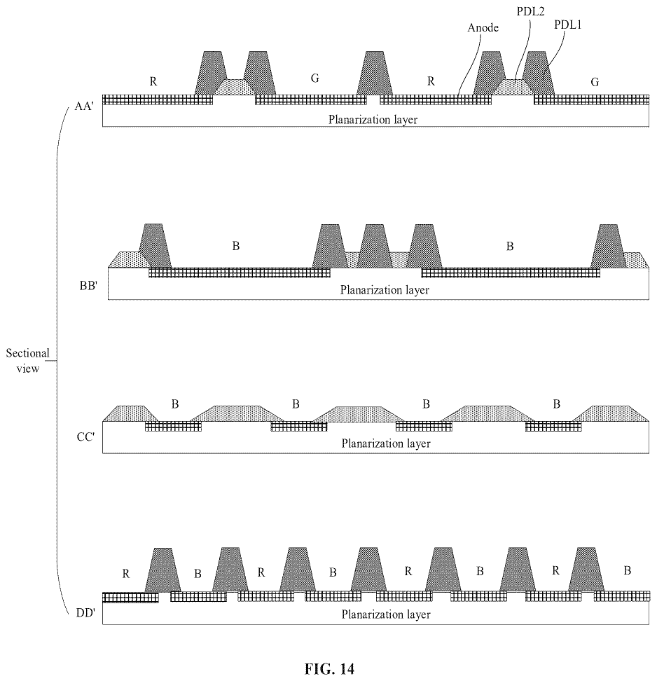

In some other embodiments, referring to a schematic structural diagram of a display panel illustrated in FIG. 9 and FIG. 13, in each column of pixels 02 documented in some embodiments of the present disclosure, the respective sub-pixels 021 and the communication portions 032 in communication with the respective sub-pixels 021 are alternately arranged in the pixel row direction X1. The orthographic projection on the substrate 01 of the communication portion 032 in communication with any adjacent two sub-pixels 021 covers the spacing region between the adjacent two sub-pixels 021. Alternatively, in some other embodiments, the orthographic projection on the substrate 01 of the communication portion 032 in communication with any adjacent two sub-pixels 021 is only overlapped with the spacing region between the adjacent two sub-pixels 021 and does not cover the entire spacing region. Optionally, FIG. 14 also illustrates a cross-sectional view of the display panel shown in FIG. 13 in a total of four directions, AA′, BB′, CC′, and DD′.

In summary, some embodiments of the present disclosure provide a display panel. The display panel includes the substrate, the plurality of pixels disposed on a side of the substrate and arranged in an array, and the pixel definition layer disposed on a side of the substrate. In the plurality of sub-pixels of different colors included in each of the pixels, at least two sub-pixels are disposed in different rows, the heterochromatic sub-pixels are disposed in different columns, and the homochromatic sub-pixels are disposed in the same column. The pixel definition layer includes the communication portion and the definition portion, and the plurality of sub-pixels are disposed within the plurality of openings defined by the communication portion and the definition portion. The communication portion is capable of being in communication with the respective homochromatic sub-pixels in the column direction, the definition portion is capable of defining the respective heterochromatic sub-pixels in the pixel row direction and the pixel column direction, and the thickness of the communication portion is smaller than the thickness of the definition portion. In this way, in one aspect, the sub-pixels of different colors are reliably defined, and in another aspect, the ink of the inkjet printing flows in the same column only towards two sides of that column, such that the film formation uniformity in the middle position is good, and thus the display effect of the display panel is good.

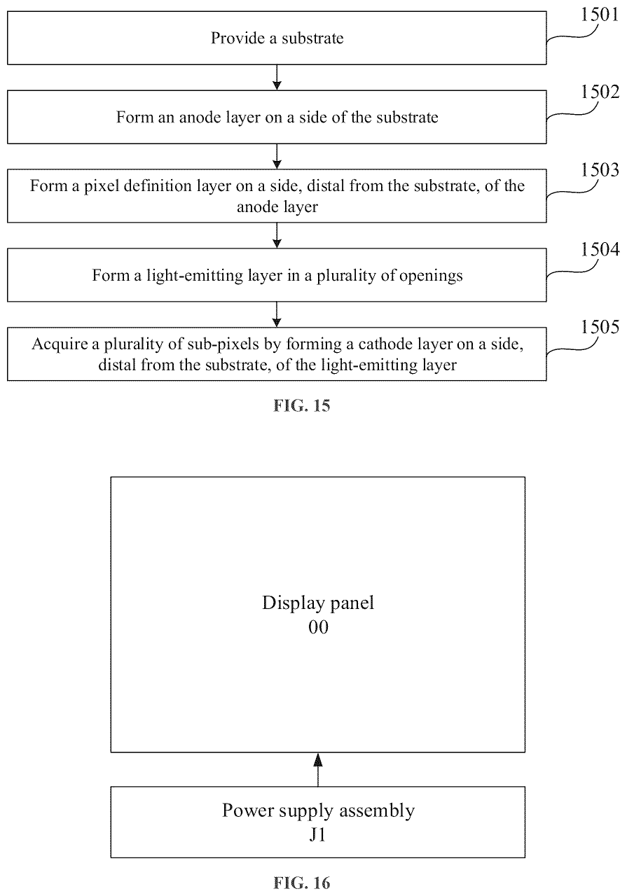

FIG. 15 is a flowchart of a method for manufacturing a display panel according to some embodiments of the present disclosure, which is applicable to manufacturing the display panel described above. As shown in FIG. 15, the method the following steps.

In step 1501, a substrate is provided.

In step 1502, an anode layer is formed on a side of the substrate.

In step 1503, a pixel definition layer is formed on a side, distal from the substrate, of the anode layer.

Referring to FIG. 3 and FIG. 4, the formed pixel definition layer 03 includes a plurality of definition portions 031 and a plurality of communication portions 032 alternately arranged along a pixel column direction Y1, and a thickness of the definition portion 031 is greater than a thickness of the communication portion 032.

A plurality of openings K1 are defined in a pixel row direction X1 and the pixel column direction Y1 by the plurality of definition portions 031 and the plurality of communication portions 032, and the pixel row direction X1 is intersected with the pixel column direction Y1.

In step 1504, light-emitting layers are formed in the plurality of openings.

Referring to FIG. 4, each of the definition portions 031 is configured to define, in the pixel row direction X1 and the pixel column direction Y1, the light-emitting layers EL in respective heterochromatic sub-pixels adjacent to each other, and each of the communication portions 032 is configured to be in communication, in the pixel column direction Y1, with the light-emitting layers EL in respective homochromatic sub-pixels adjacent to each other.

In step 1505, a plurality of sub-pixels is acquired by forming a cathode layer on a side, distal from the substrate, of the light-emitting layer.

Referring to FIG. 3, each of the formed pixels 02 includes a plurality of sub-pixels 021 of different colors. In each of the pixels 02, at least two of the sub-pixels 021 are disposed in different rows, and the respective sub-pixels 021 are disposed in different columns. An area of an orthographic projection of each of the sub-pixels 021 on the substrate 01 is positively correlated to a decay rate of the sub-pixel 021.

In some embodiments, step 1503, i.e., forming the pixel definition layer on the side, distal from the substrate, of the anode layer, includes: forming a first pixel definition layer and a second pixel definition layer on the side, distal from the substrate, of the anode layer, using a half-tone mask plate. In this way, the manufacturing schedule is accelerated and the manufacturing cost is saved.

Referring to FIG. 3 and FIG. 4, the formed first pixel definition layer PDL1 includes a plurality of definition portions 031 and the formed second pixel definition layer PDL2 includes a plurality of communication portions 032. The first pixel definition layer PDL1 is made of a lyophobic material, and the second pixel definition layer PDL2 is made of a lyophilic material.

In some embodiments, step 1504, i.e., forming the light-emitting layers in the plurality of openings, includes: forming the light-emitting layers by printing light-emitting materials in the plurality of openings by an inkjet printing process.

In some embodiments, the display panel further includes a pixel circuit coupled to the sub-pixels. The pixel circuit generally includes transistors and capacitors. In some embodiments, the pixel circuit is a 7T1C structure (i.e., including 7 transistors and 1 capacitor). The sub-pixel includes an anode layer Anode, a light-emitting layer EL, and a cathode layer Cathode. Based on this, a method for manufacturing the display panel is described as follows.

First, a pixel circuit, i.e., a transistor such as a thin film transistor (TFT), is prepared in a light-emitting region on a side of the substrate 01, and the substrate 01 including the TFT is referred to as a TFT substrate. Then, a planarization layer is prepared on a side of the TFT substrate for subsequent reliable film formation on the TFT substrate. Then, an anode layer Anode is prepared on a side, distal from the TFT substrate, of the planarization layer, the anode layer Anode is made of indium tin oxide (ITO), and the shape of the prepared ITO is consistent with the shape of the sub-pixel that ultimately need to be formed. That is, the anode ITO is prepared on a side of the TFT substrate. Then again, a first pixel definition layer PDL1 and a second pixel definition layer PDL2 are prepared on a side, distal from the TFT substrate, of the anode ITO using a half-tone mask plate for defining respective sub-pixels. For the formed first pixel definition layer PDL1 and the second pixel definition layer PDL2, reference is made to the embodiments described above. Afterward, an inkjet printing process is used to print the light-emitting layer EL in the opening K1 defined by the first pixel definition layer PDL1 and the second pixel definition layer PDL2, such that the homochromatic sub-pixels in each column are intercommunicated and the heterochromatic sub-pixels in each row are defined. The printed light-emitting layer EL includes a hole injection layer (HIL), a hole transport layer (HTL), and the like. Finally, the cathode layer Cathode is formed on a side, distal from the TFT substrate, of the light-emitting layer EL, and a package layer is formed on a side, distal from the TFT substrate, of the cathode layer Cathode to complete the package.

In summary, some embodiments of the present disclosure provide a method for manufacturing a display panel. The display panel manufactured by the method includes the substrate, the plurality of pixels disposed on a side of the substrate and arranged in an array, and the pixel definition layer disposed on a side of the substrate. In the plurality of sub-pixels of different colors included in each of the pixels, at least two sub-pixels are disposed in different rows, the heterochromatic sub-pixels are disposed in different columns, and the homochromatic sub-pixels are disposed in the same column. The pixel definition layer includes the communication portion and the definition portion, and the plurality of sub-pixels are disposed within the plurality of openings defined by the communication portion and the definition portion. The communication portion is capable of being in communication with the respective homochromatic sub-pixels in the column direction, the definition portion is capable of defining the respective heterochromatic sub-pixels in the pixel row direction and the pixel column direction, and the thickness of the communication portion is smaller than the thickness of the definition portion. In this way, in one aspect, the sub-pixels of different colors are reliably defined, and in another aspect, the ink of the inkjet printing flows in the same column only towards two sides of that column, such that the film formation uniformity in the middle position is good, and thus the display effect of the display panel is good.

FIG. 16 is a schematic structural diagram of a display device according to some embodiments of the present disclosure. As shown in FIG. 16, the display device includes a power supply assembly J1 and a display panel 00 as described above.

The power supply assembly J1 is coupled to the display panel 00 and is configured to supply power to the display panel 00.

In some embodiments, the display device is an OLED device, a smartphone, a tablet computer, a television, a monitor, or any other product or component with a display function.

It should be noted that in the accompanying drawings, the sizes of layers and regions may be exaggerated for clearer illustration. It should be understood that where an element or layer is referred to as being “on” another element or layer, the element or layer may be directly on another element, or intervening layers therebetween may be present. In addition, it should be understood that where an element or layer is referred to as being “under” another element or layer, the element or layer may be directly under the other element, or there may be more than one intervening layer or element. In addition, it may be further understood that in the case that a layer or element is referred to as being “between” two layers or two elements, the layer may be the only layer between the two layers or two elements, or more than one intervening layer or element may further be present. Like reference numerals indicate like elements throughout.

The terms used in the detailed description of the present disclosure are merely for interpreting, instead of limiting, the embodiments of the present disclosure. It should be noted that unless otherwise defined, technical or scientific terms used in the embodiments of the present disclosure shall have ordinary meanings understandable by persons of ordinary skill in the art to which the disclosure belongs.

In the present disclosure, the terms “first” and “second” are only used for descriptive purposes, and cannot be understood as indicating or implying relative importance. The term “a plurality of” refers to two or more, unless expressly defined otherwise.

Similarly, the terms “one” or “one” and the like do not indicate a quantitative limitation, but rather the presence of at least one.

The terms “comprise,” “include,” and derivatives or variations thereof are used to indicate that the element or object preceding the terms covers the element or object following the terms and its equivalents, and shall not be understood as excluding other elements or objects.

The terms “on,” “under,” “left,” and “right” are only used to indicate the relative positional relationship. When the absolute position of the described object changes, the relative positional relationship may change accordingly. The term “connect” or “couple” refers to an electrical connection.

The term “and/or” mentioned in the embodiments of the present disclosure indicates three relationships between contextual objects. In some embodiments, A and/or B may mean that A exists alone, A and B exist at the same time, and B exists alone. The symbol “/” generally denotes an “OR” relationship between contextual objects.

Described above are merely exemplary embodiments of the present disclosure, and are not intended to limit the present disclosure. Therefore, any modifications, equivalent substitutions, improvements, and the like made within the spirit and principles of the present disclosure shall be included in the protection scope of the present disclosure.

1. A display panel, comprising:
a substrate;
a plurality of pixels disposed on a side of the substrate and arranged in an array, each of the pixels comprising a plurality of sub-pixels of different colors; wherein in each of the pixels, at least two sub-pixels are disposed in different rows, homochromatic sub-pixels are disposed in a same column, heterochromatic sub-pixels are disposed in different columns, and an area of an orthographic projection of each of the sub-pixels on the substrate is positively correlated with a decay rate of luminance of the sub-pixel; and
a pixel definition layer, disposed on a side of the substrate and comprising a plurality of definition portions and a plurality of communication portions alternately arranged along a pixel column direction; wherein a plurality of openings are defined by the plurality of definition portions and the plurality of communication portions in a pixel row direction and the pixel column direction, and the plurality of sub-pixels in the display panel are disposed within the plurality of openings, the pixel row direction being intersected with the pixel column direction; and each of the definition portions is configured to define, in the pixel row direction and the pixel column direction, the respective heterochromatic sub-pixels adjacent to each other, each of the communication portions is configured to be in communication, in the pixel column direction, with the respective homochromatic sub-pixels adjacent to each other, and a thickness of the definition portion is greater than a thickness of the communication portion.

2. The display panel according to claim 1, wherein in each column of the pixels, each column of the sub-pixels disposed at two edges and the communication portion in communication with each column of the sub-pixels are successively arranged along the pixel column direction, and the communication portion in communication with each column of the sub-pixels covers a portion, extending away from the definition portion in the pixel column direction, of each of the sub-pixels; and in each column of the sub-pixels disposed in a middle, the respective sub-pixels and the communication portion in communication with the respective sub-pixels are successively arranged along the pixel row direction.

3. The display panel according to claim 2, wherein portions, covering the respective sub-pixels, of the communication portion are in communication with each other in the pixel row direction.

4. The display panel according to claim 2, wherein portions, covering the respective sub-pixels, of the communication portion are independent from each other in the pixel row direction.

5. The display panel according to claim 4, wherein in the pixel row direction, an orthographic projection on the substrate of the portion, covering each of the sub-pixels, of the communication portion is overlapped with a spacing region between adjacent two of the sub-pixels.

6. The display panel according to claim 1, wherein in each column of the pixels, the respective sub-pixels and the communication portion in communication with the respective sub-pixels are alternately arranged in the pixel row direction.

7. The display panel according to claim 6, wherein an orthographic projection of the communication portion in communication with any adjacent two of the sub-pixels on the substrate covers a spacing region between the adjacent two sub-pixels.

8. The display panel according to claim 1, wherein an orthographic projection of the sub-pixel on the substrate is any one of the following shapes: rectangular, polygonal, L-shaped, T-shaped, or cross-shaped.

9. The display panel according to claim 8, wherein in the plurality of sub-pixels in each of the pixels, in the pixel column direction, each of the sub-pixels disposed at the two edges is L-shaped or T-shaped, and the sub-pixel disposed in the middle is T-shaped or cross-shaped.

10. The display panel according to claim 9, wherein in the pixel row direction,
in the pixels in first and last rows, each of the sub-pixels disposed at the two edges is L-shaped, and the sub-pixel disposed in the middle is T-shaped or cross-shaped; and
in the pixels in rows other than the first and last rows, each of the sub-pixels disposed at the two edges is T-shaped, and the sub-pixel disposed in the middle is cross-shaped.

11. The display panel according to claim 1, wherein an orthographic projection of each of the pixels on the substrate is triangular, and each of the pixels comprises a first sub-pixel, a second sub-pixel, and a third sub-pixel of different colors; wherein
the first sub-pixel and the second sub-pixel are disposed in a same row, and are both disposed in a row different from the third sub-pixel; and the third sub-pixel comprises a first portion, a second portion, and a third portion arranged in the pixel column direction, wherein the first portion and the first sub-pixel are disposed in a same column, the third portion and the second sub-pixel are disposed in a same column, and the second portion, the first sub-pixel and the second sub-pixel are disposed in different columns.

12. The display panel according to claim 11, wherein
the first sub-pixel is a red sub-pixel, the second sub-pixel is a green sub-pixel, and the third sub-pixel is a blue sub-pixel; and
an area of an orthographic projection of the first sub-pixel on the substrate is equal to an area of an orthographic projection of the second sub-pixel on the substrate, and both of the areas are smaller than an area of an orthographic projection of the third sub-pixel on the substrate.

13. The display panel according to claim 1, wherein the pixel definition layer comprises a first pixel definition layer and a second pixel definition layer that are disposed on a side of the substrate; wherein
the first pixel definition layer comprises the plurality of definition portions and the second pixel definition layer comprises the plurality of communication portions; and
the first pixel definition layer is made of a lyophobic material, and the second pixel definition layer is made of a lyophilic material.

14. The display panel according to claim 13, wherein in a direction perpendicular to the substrate, a cross-section of the first pixel definition layer is in a regularly trapezoidal shape.

15. The display panel according to claim 1, wherein a thickness of the definition portion ranges from 1.2 micrometers to 1.5 micrometers, and a thickness of the communication portion ranges from 0.3 micrometers to 1 micrometer.

16. The display panel according to claim 1, wherein the sub-pixel comprises an anode layer, a light-emitting layer, and a cathode layer that are successively stacked in a direction away from the substrate;
wherein the anode layer is disposed within the opening, the definition portion is configured to define the light-emitting layers contained in the respective heterochromatic sub-pixels adjacent to each other, and the communication portion is configured to be in communication with the light-emitting layers contained in the respective homochromatic sub-pixels adjacent to each other.

17. A method of manufacturing a display panel, applicable to manufacturing the display panel as defined in claim 1; the method comprising:
providing a substrate;
forming an anode layer on a side of the substrate;
forming a pixel definition layer on a side, distal from the substrate, of the anode layer; wherein the formed pixel definition layer comprises a plurality of definition portions and a plurality of communication portions alternately arranged along a pixel column direction, a thickness of the definition portion is greater than a thickness of the communication portion, and a plurality of openings are defined by the plurality of definition portions and the plurality of communication portions in a pixel row direction and the pixel column direction, the pixel row direction being intersected with the pixel column direction;
forming light-emitting layers in the plurality of openings; wherein each of the definition portions is configured to define, in the pixel row direction and the pixel column direction, the light-emitting layers in respective heterochromatic sub-pixels adjacent to each other, and each of the communication portions is configured to be in communication, in the pixel column direction, with the light-emitting layers in respective homochromatic sub-pixel adjacent to each other; and
acquiring a plurality of sub-pixels by forming a cathode layer on a side, distal from the substrate, of the light-emitting layer;
wherein each of the formed pixels comprises the plurality of sub-pixels of different colors, in each of the pixels, at least two sub-pixels are disposed in different rows, the respective sub-pixels are disposed in different columns, and an area of an orthographic projection of each of the sub-pixels on the substrate is positively correlated with a decay rate of the sub-pixel.

18. The method according to claim 17, wherein forming the pixel definition layer on the side, distal from the substrate, of the anode layer comprises:
forming a first pixel definition layer and a second pixel definition layer on the side, distal from the substrate, of the anode layer using a half-tone mask plate; wherein
the formed first pixel definition layer comprises the plurality of definition portions and the formed second pixel definition layer comprises the plurality of communication portions; and
the first pixel definition layer is made of a lyophobic material, and the second pixel definition layer is made of a lyophilic material.

19. The method according to claim 17, wherein forming the light-emitting layers in the plurality of openings comprises:
forming the light-emitting layers by printing light-emitting materials in the plurality of openings by an inkjet printing process.

20. A display device, comprising: a power supply assembly and a display panel; wherein
the power supply assembly is coupled to the display panel and is configured to supply power to the display panel; and
the display panel comprises:
a substrate;
a plurality of pixels disposed on a side of the substrate and arranged in an array, each of the pixels comprising a plurality of sub-pixels of different colors; wherein in each of the pixels, at least two sub-pixels are disposed in different rows, homochromatic sub-pixels are disposed in a same column, heterochromatic sub-pixels are disposed in different columns, and an area of an orthographic projection of each of the sub-pixels on the substrate is positively correlated with a decay rate of luminance of the sub-pixel; and
a pixel definition layer, disposed on a side of the substrate and comprising a plurality of definition portions and a plurality of communication portions alternately arranged along a pixel column direction; wherein a plurality of openings are defined by the plurality of definition portions and the plurality of communication portions in a pixel row direction and the pixel column direction, and the plurality of sub-pixels in the display panel are disposed within the plurality of openings, the pixel row direction being intersected with the pixel column direction; and each of the definition portions is configured to define, in the pixel row direction and the pixel column direction, the respective heterochromatic sub-pixels adjacent to each other, each of the communication portions is configured to be in communication, in the pixel column direction, with the respective homochromatic sub-pixels adjacent to each other, and a thickness of the definition portion is greater than a thickness of the communication portion.
